(19) United States
(12) Patent Application Publication
(10) Pub. No.: US 2007/0028842 A1
(43) Pub. Date: Feb. 8, 2007

(54) Vacuum chamber bottom

(76) Inventors: Makoto Inagawa, Palo Alto, CA (US); Akihiro Hosokawa, Cupertino, CA (US)

Correspondence Address: PATTERSON & SHERIDAN, LLP, 3040 POST OAK BOULEVARD, SUITE 1500, HOUSTON, TX, 77056, US

(21) Appl. No.: 11/213,667

(22) Filed: Aug. 24, 2005

Related U.S. Application Data
(60) Provisional application No. 60/705,031, filed on Aug. 2, 2005.

(51) Int. Cl. C23C 16/00

(52) U.S. Cl. 118/728; 118/719

(57) ABSTRACT

A process chamber having an reinforced chamber body is provided. The reinforced chamber body may include one or more chamber walls, a chamber bottom, and a chamber support assembly attached to an exterior side of the chamber bottom. The chamber support assembly may include one or more elongated base support structures and one or more lateral support structures connected to the one or more elongated base support structures. The process chamber may also include a plurality of substrate support pins attached to an interior side of the chamber bottom and adapted to support a large area substrate thereon.

### CROSS-REFERENCE TO RELATED APPLICATIONS

This application claims benefit of U.S. provisional patent application Ser. No. 60/705,031 (AMAT/10232L), filed Aug. 2, 2005, which is herein incorporated by reference.

### BACKGROUND OF THE INVENTION

Liquid crystal displays or flat panel displays (FPD) are commonly used for active matrix displays such as computer and television monitors, personal digital assistants (PDAs), and cell phones, as well as solar cells and the like. Generally, a flat panel display comprises two glass plates having a layer of liquid crystal material sandwiched therebetween. At least one of the glass plates includes at least one conductive film disposed thereon that is coupled to a power supply. Power supplied to the conductive film from the power supply changes the orientation of the crystal material, creating a pattern such as texts or graphics on the flat panel displays. Fabrication processes frequently employed to produce flat panel displays includes chemical vapor deposition (CVD) and physical vapor deposition (PVD), which often function at low pressure or high vacuum conditions.

Substrates utilized for flat panel fabrication are large in size, often exceeding 550 mm×650 mm, and are envisioned up to and beyond 4 square meters in surface area. Correspondingly, CVD and PVD process chambers utilized to process large area substrates are proportionately very large, range from 0.5 to 2 meters per side and may be ever larger in the near future to accommodate the large surface area of the substrates. However, increasing the size of the substrates and process chambers increases vacuum induced stress in various process chamber components, especially the chamber body, in order to sustain the vacuum level and the integrity of the process chambers. Consequently, the thickness of the chamber body, are often made quite thick, such as about 2 to 4 inches or more, in order to provide enough structural support for chamber components and sustain the high vacuum induced stress. However, the increased chamber dimension and increased thickness of the process chamber component result in greater weight, increased difficulty in manufacture, and higher cost. Thus, the process chamber body, especially the chamber bottom, may need to be reinforced such that it can be constructed in thinner thickness to ease the manufacture of the process chamber and reduce the chamber weight.

Therefore, there is a need for an improved apparatus with reinforced chamber body and reduced chamber weight and still sustain the vacuum induced stress, and a method to manufacture the apparatus.

### SUMMARY OF THE INVENTION

Embodiments of a process chamber and a reinforced chamber body are provided. In one embodiment of the invention, a process chamber includes. In another embodiment, a chamber body for a chamber adapted to support a large area substrate therein includes one or more chamber walls, a chamber bottom, and a chamber support assembly attached an exterior side of the chamber bottom. The chamber support assembly includes one or more elongated base support structures and one or more lateral support structures.

In another embodiment, a process chamber for processing a large area substrate therein includes a chamber body and a plurality of substrate support pins. The chamber body includes one or more chamber walls and a chamber bottom. The substrate support pins may be attached to an interior side of the chamber bottom.

In yet another embodiment, a method of reinforcing a chamber bottom of a vacuum chamber includes providing a plurality of elongated base support structures in a first direction and providing a plurality of lateral support structures in a second direction. The method further includes attaching the elongated base support structures and the lateral support structures to the chamber bottom of the vacuum chamber.

In still another embodiment, a method of transferring a substrate into a chamber having a susceptor therein is provided. The method includes providing a plurality of substrate support pins attached to an interior side of the bottom of the chamber, placing the substrate onto the plurality of the substrate support pins, and moving the susceptor in a vertical direction to lift the substrate from the plurality of the substrate support pins.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments. To facilitate understanding, identical reference numerals have been used, where possible, to designate identical elements that are common to the figures.

FIG. 1 depicts a schematic sectional view of a PVD process chamber having a unitary chamber body.

FIG. 2 depicts a schematic sectional view of one embodiment of a process chamber body having a reinforced chamber bottom of the invention.

FIG. 3 is a bottom view of an exemplary reinforced chamber bottom according to one embodiment of the invention.

FIG. 4 is a schematic sectional view of an exemplary chamber body according to one embodiment of the invention.

FIG. 5 is a top view of an exemplary reinforced chamber bottom according to one embodiment of the invention.

### DETAILED DESCRIPTION

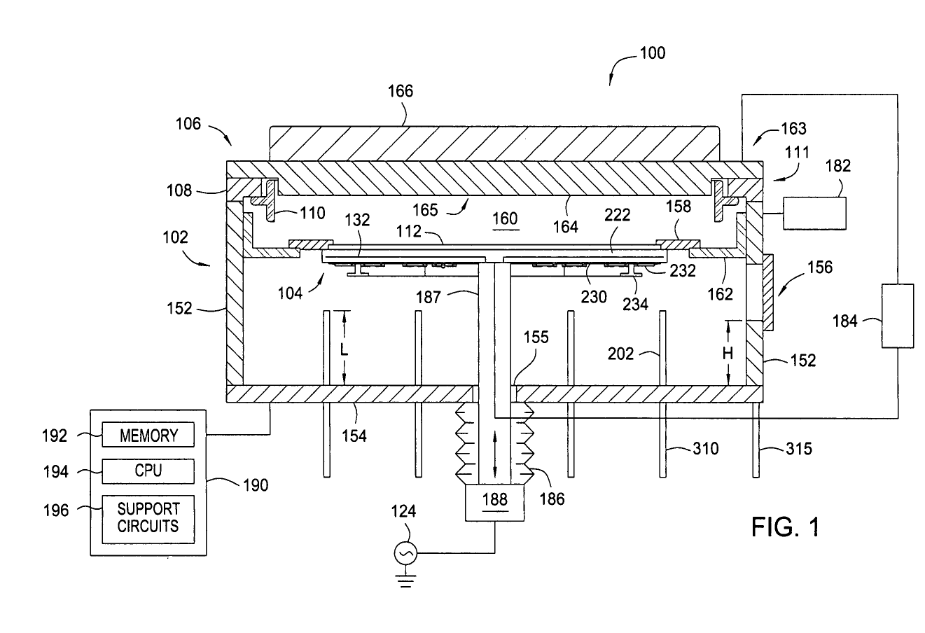

The invention provides a reinforced chamber body, particularly a reinforced chamber bottom, for a process chamber, and a method to manufacture the process chamber for processing a large area substrate. FIG. 1 illustrates an exemplary process chamber 100 according to one embodiment of the invention. The invention is illustratively described below in reference to a physical vapor deposition process chamber for processing large area substrates, such as those available from AKT, a division of Applied Materials, Inc., Santa Clara, Calif. However, it should be understood that the invention has utility in other system configurations such as physical vapor deposition systems, ion implant systems, etch systems, chemical vapor deposition systems, transfer chambers, thermal chambers, and any other system in which reinforcement of a chamber body within a chamber is desired.

The process chamber 100 includes a chamber body 102, a substrate support assembly 104, and a lid assembly 106, defining a process volume. The chamber body 102 is typically fabricated from metal or metal alloy materials, such as a unitary block of aluminum or welded stainless steel plates. The chamber body 102 generally includes chamber sidewalls 152 and a chamber bottom 154. One embodiment of the invention provides a reinforced chamber body. For example, the chamber bottom 154 of the invention can be reinforced with a chamber support assembly 310, which will be described in detail below.

The lid assembly 106 generally includes a target 164 and a ground shield assembly 111 coupled thereto. Optionally, the lid assembly 106 may further comprise a magnetron assembly 166, which enhances consumption of the target material during processing. Examples of the magnetron assembly include a linear magnetron, a serpentine magnetron, a spiral magnetron, a double-digitated magnetron, a rectangularized spiral magnetron, among others.

The target 164 provides a material source that can be deposited onto the surface of a substrate 112 during a PVD process. The target 164 or target plate may be fabricated of a material that will become the deposition species or it may contain a coating of the deposition species. To facilitate sputtering, a high voltage power supply, such as a power source 184 is connected to the target 164 and to the substrate support assembly 104.

The target 164 generally includes a peripheral portion 163 and a central portion 165. The peripheral portion 163 is disposed over the sidewalls 152 of the chamber. The central portion 165 of the target 164 may protrude, or extend in a direction towards the substrate support assembly 104. It is contemplated that other target configurations may be utilized as well. For example, the target 164 may comprise a backing plate having a central portion of a desired material bonded or attached thereto. The target material may also comprise adjacent tiles or segments of material that together form the target.

During a sputtering process to deposit a material on the substrate 112, the target 164 and the substrate support assembly 104 are biased relative each other by the power source 184. A process gas, such as inert gas and other gases, e.g., argon, and nitrogen, is supplied to the process volume 160 from a gas source 182 through one or more apertures (not shown), typically formed in the sidewalls 152 of the process chamber 100. The process gas is ignited into a plasma and ions within the plasma are accelerated toward the target 164 to cause target material to be dislodged from the target 164 into particles. The dislodged material or particles are attracted towards the substrate 112 through the applied bias, depositing a film of material onto the substrate 112.

The ground shield assembly 111 includes a ground frame 108, a ground shield 110, or any chamber shield member, target shield member, dark space shield, dark space shield frame, etc. The ground shield 110 surrounds the central portion 165 of the target 164 to define a processing region within the process volume 160 and is coupled to the peripheral portion 163 of the target 164 by the ground frame 108. The ground frame 108 electrically insulates the ground shield 110 from the target 164 while providing a ground path to the chamber body 102 of the process chamber 100 (typically through the sidewalls 152).

The ground shield 110 constrains the plasma within the region circumscribed by the ground shield 110 to ensure that target source material is only dislodged from the central portion 165 of the target 164. The ground shield 110 may also facilitate depositing the dislodged target source material mainly on the substrate 112. This maximizes the efficient use of the target material as well as protects other regions of the chamber body 102 from deposition or attack from the dislodged species or from the plasma, thereby enhancing chamber longevity and reducing the downtime and cost required to clean or otherwise maintain the chamber. The ground shield 110 may be formed of one or more work-piece fragments and/or one or more corner pieces, and a number of these pieces are bonded together, using bonding processes known in the art, such as welding, gluing, high pressure compression, etc.

The substrate support assembly 104 is generally disposed on the chamber bottom 154 of the chamber body 102. The substrate support assembly 104 may include a plate-like body, such as a susceptor 222, which is thermally conductive to support and provide temperature control to the substrate 112 thereon during substrate processing within the process chamber 100. Suitable metal or metal alloy materials, such as stainless steel, aluminum, etc., are used to manufacture the body of the susceptor 222. Optionally, the substrate support assembly 104 of the invention may further include a cooling plate 230, one or more cooling channels 232, and a susceptor base support structure 234. The susceptor 222 of the invention includes one or more electrodes and/or heating elements 132 coupled to a heating power source 124 to controllably heat the substrate support assembly 104 and the substrate 112 positioned thereon to a predetermined temperature of about 60° C. or higher, such as between about 100° C. to about 200° C.

As shown in FIG. 1, a shadow frame 158 and a chamber shield 162 may be disposed within the chamber body 102. The shadow frame 158 is generally configured to confine deposition to a portion of the substrate 112 exposed through the center of the shadow frame 158. The shadow frame 158 can be formed of one piece or it can be two or more work-piece fragments bonded together in order to surround the peripheral portions of the substrate 112.

In one embodiment, the substrate support assembly 104 of the process chamber 100 of the invention is adapted to process a rectangular substrate. The surface area of a rectangular substrate for flat panel display is typically large, for example, a rectangle of about one square meter or larger, such as at least about 370 mm by about 470 mm. For flat panel display application, the substrate 112 may comprise a material that is essentially optically transparent in the visible spectrum, for example glass or clear plastic. However, the invention is equally applicable to substrate processing of any types and sizes. Substrates of the invention can be circular, square, rectangular, or polygonal for flat panel display manufacturing. In addition, the invention applies to substrates for fabricating any devices, such as flat panel display (FPD), flexible display, organic light emitting diode (OLED) displays, flexible organic light emitting diode (FOLED) display, polymer light emitting diode (PLED) display, liquid crystal displays (LCD), organic thin film transistor, active matrix, passive matrix, top emission device, bottom emission device, solar cell, solar panel, etc., and can be on any of the silicon wafers, glass substrates, metal substrates, plastic films (e.g., polyethylene terephthalate (PET), polyethylene naphthalate (PEN), etc.), plastic epoxy films, among others.

A controller 190 is included to interface with and control various components of the process chamber 100. The controller 190 typically includes a central processing unit (CPU) 194, support circuits 196 and a memory 192. The CPU 194 may be one of any forms of computer processors that can be used in an industrial setting for controlling various chambers, apparatuses, and chamber peripherals. The memory 192, any software, or any computer-readable medium coupled to the CPU 194 may be one or more readily available memory devices, such as random access memory (RAM), read only memory (ROM), hard disk, CD, floppy disk, or any other form of digital storage, for local or remote for memory storage. The support circuits 196 are coupled to the CPU 194 for supporting the CPU 194 in a conventional manner. These circuits include cache, power supplies, clock circuits, input/output circuitry, subsystems, and the like.

PVD chambers that may be adapted to benefit from the invention are described in co-pending U.S. patent application Ser. No. 11/131,009 (docket number: AMAT/9566) filed on May 16, 2005, titled “Ground Shield for a PVD chamber” by Golubovsky; (docket number: AMAT/10169) titled “Integrated PVD System Using Designated PVD Chambers” by Hosokawa et al.; and (docket number: AMAT/10232), titled “Heating and cooling of Substrate Support” by Inagawa et al., all of which are hereby incorporated by reference in their entireties.

The dimensions of the chamber body 102 and related components of the process chamber 100 are not limited and generally are proportionally larger than the size and dimension of the substrate 112 to be processed in the process chamber 100. For example, when processing a large area square substrate having a width of about 370 mm to about 2160 mm and a length of about 470 mm to about 2460 mm, the chamber body 102 may include a width of about 570 mm to about 2360 mm and a length of about 570 mm to about 2660 mm. As another example, when processing a substrate size of about 1950 mm×2250 mm, the chamber body 102 can have a cross sectional dimension of about 2700 mm×3000 mm.

The chamber body 102, the chamber sidewalls 152, and/or the chamber bottom 154 generally include a plurality of apertures, such as a lift assembly port 155, an access port 156, and a pumping port 157. The access port 156 is sealable, such as by a slit valve, a gate valve, or other vacuum sealable assembly, and may be coupled to a transfer chamber of a cluster substrate processing system to provide entrance and egress of the substrate 112 (e.g., a flat panel display substrate or a semiconductor wafer) into and out of the process chamber 100. Other apertures may also optionally be formed on the chamber sidewalls 152 and/or the chamber bottom 154 of the chamber body 102.

A shaft 187 extends through the chamber bottom 154 of the chamber body 102 and couples the substrate support assembly 104 to a lift mechanism 188 through the lift assembly port 155. The lift mechanism 188 is configured to move the substrate support assembly 104 between a lower substrate loading/unloading position and an upper substrate processing position. The substrate support assembly 104 is depicted in an intermediate position in FIG. 1. A bellows 186 is typically disposed between the substrate support assembly 104 and the chamber bottom 154 and provides a flexible seal therebetween, thereby maintaining vacuum integrity of the chamber volume 160.

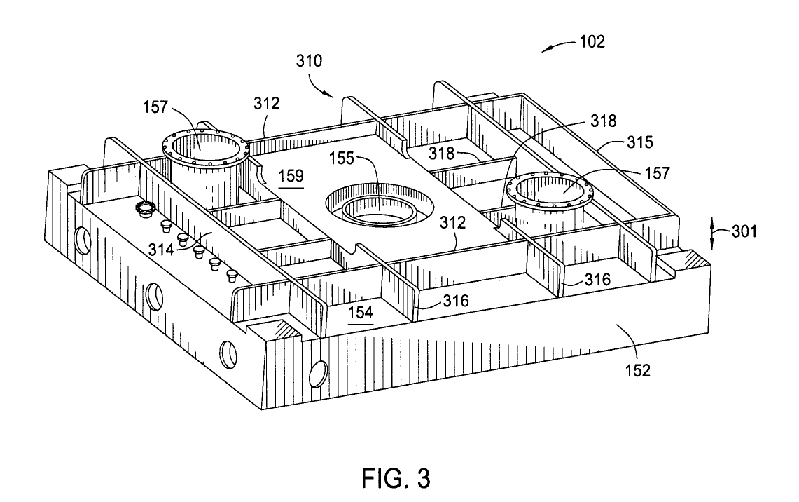

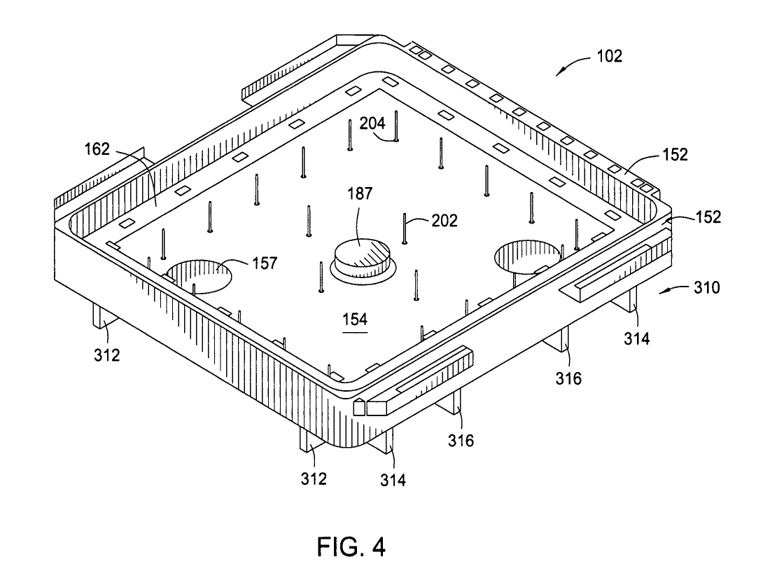

The pumping port 157 may be coupled to a pumping device (not shown), such as a cryogenic pump, a dry pump, a roughing pump, a turbo pump, and a cryogenic pump, among others, which evacuates and controls the pressure within the process volume 160. The pumping device is able to maintain the pressure of the process chamber 100 to a high vacuum level. For example, the pressure level of the process chamber 100 can be maintained to about 1 Torr or less, such as at about 10⁻³ Torr or less, at about 10⁻⁵ Torr to about 10⁻⁷ Torr, or at about 10⁻⁷ Torr or less. In one embodiment, one or more pumping devices coupled to one or more pumping ports 157 can be used. In another embodiment, two or more pumping ports 157, as shown in FIGS. 3 and 4, coupled to two or more pumping devices are configured to be used for the large processing volume of the large dimension process chamber 100. In addition, the two or more pumping ports 157 will allow service and maintenance of one pumping device possible while the other pumping device is still functional to control the pressure inside the process chamber 100. Thus, the chance of chamber down time due to pumping device problem is reduced. In one aspect, two or more less expansive pumping devices can be coupled to the process chamber 100 to save cost and are still able to maintain high vacuum level for the process chamber 100.

When the substrate support assembly 104 is moved to the upper substrate processing position, an outer edge of the substrate 112 disposed on the substrate support assembly 104 engages the shadow frame 158 and lifts the shadow frame 158 from the chamber shield 162. When the substrate support assembly 104 is moved into the lower substrate loading/unloading position, the substrate support assembly 104 is positioned below the chamber shield 162 and the access port 156. The substrate 112 may then be removed from or placed into the process chamber 100 through the access port 156 on the chamber sidewalls 152 using the transfer robot, and at this point, the substrate 112 can be temporarily supported by one or more substrate support pins 202.

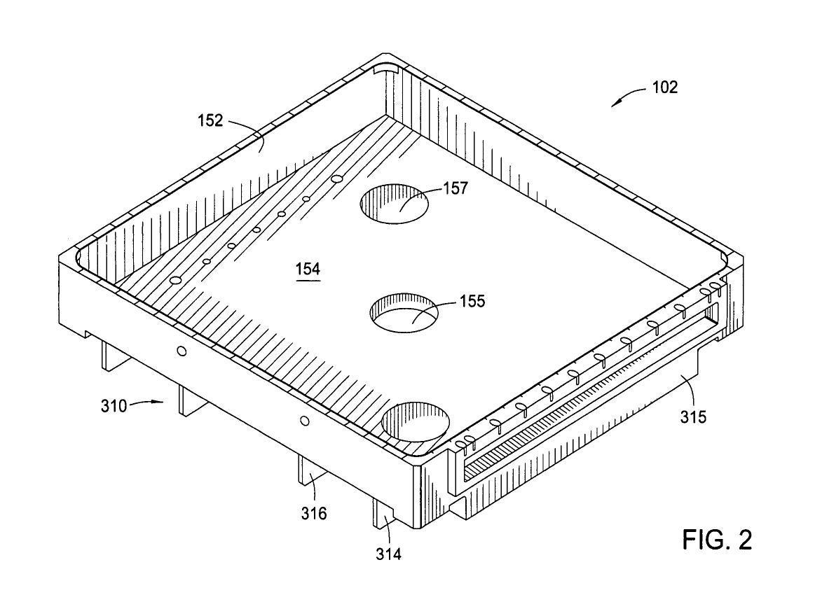

FIGS. 2 and 3 are examples of the chamber body 102 having the chamber support assembly 310 in its fully assembled exemplary configuration in accordance with one or more aspects of the invention. In one embodiment, the chamber support assembly 310 is attached to an exterior side of the chamber bottom 154. The chamber support assembly 310 generally includes one or more elongated base support structures 312, one or more lateral support structures 314, 316, one or more cross support structures 318, and an additional support structure 315. In one embodiment, the components of the chamber support assembly 310 are generally bonded together and attached to the chamber bottom 154, using bonding processes known in the art, such as welding, machining, gluing, high pressure compression, etc. In another embodiment, the components of the chamber support assembly 310 can be machined from a unitary block of metal materials.

In order to reduce the weight of the large dimension of the chamber body 102, one embodiment of the invention provides reinforcement of the chamber body 102 with the chamber support assembly 310 such that the thickness of the chamber body 102, including the chamber wall 152 and/or the chamber bottom 154, can be reduced to about one inch or less, such as about 0.75 inch or less. Previous chamber body designs may have a chamber body thickness of about 2 inch to about 4 inch, which, for processing a large dimension substrate, translates to a very heavy and hard to manufacture chamber body. In another embodiment, the chamber support assembly 310 provides supports to the chamber body 102, the substrate support assembly 104, the substrate support pins 202, and the substrate 112 thereon to prevent them from deformation, sagging, and deflection due to weight, gravity, high pressure, and high temperature, etc. during substrate processing.

The elongated base support structures 312, the lateral support structures 314, 316, the cross support structures 318, and the additional support structure 315 may be configured as beam-like or rib-like structures with different sizes, dimension, shapes, and cut-outs, and may generally include a height 301 to provide stiffness and mechanical support to the chamber body 102. The height 301 may be about one inch or larger, such as about four inches or larger or between about six inches to about eight inches. The thickness of these structures is not limiting and may generally be about two inches or less, such as about one inch or less.

In one aspect, it is preferred that the elongated base support structures 312, the lateral support structures 314, 316, the cross support structures 318, and the additional support structure 315 be fabricated from a material of sufficient strength and rigidity to support and retain the weight of the chamber body 102 under the processing temperature and pressure conditions. For example, the elongated base support structures 312, the lateral support structures 314, 316, the cross support structures 318, and the additional support structure 315 are made from a metal or a metal alloy material, aluminum, stainless steel, such as a heat resistant metal 300 series stainless steel or a ceramic alumina material (Al₂O₃), etc.

The elongated base support structures 312 are generally disposed along the length of the chamber bottom 154 and may include a length which is about the length of the chamber bottom 154. The lateral support structures 314, 316 are generally disposed along the width of the chamber bottom 154 and configured to be connected to the elongated base support structures 312. The lateral support structures 314, 316 are generally may include a length which is about the width of the chamber bottom 154. The lateral support structures 316 are positioned near the lift assembly port 155 and may include cut-outs to provide space for accommodating components for the shaft 187, the lift mechanism 188, the bellow 186, the lift assembly port 155, the pumping port 157, and an optional horizontal support plate 159. The optional horizontal support plate may be configured horizontally near the lift assembly port 155 to surround the elongated base support structures 312, the lateral support structures 314, 316, the cross support structures 318 and provide additional mechanical supports thereof and secure these support structures in place.

The cross support structures 318 are positioned near the lift assembly port 155 along the length of the chamber bottom 154 and may include a shorter length than the elongated base support structures 312 and a shorter height due to spatial constraints for various chamber components near the lift assembly port 155. The cross support structures 318 are adapted to provide additional support near the central portion of the chamber body 102 and may be configured to be connected to and extend across the lateral support structures 314, 316 in a configuration that is generally transverse to the lateral support structures 314, 316.

The chamber support assembly 310 may include additional support structures below each side of the chamber wall 152 to support the weight of the chamber wall or strengthen the chamber wall 152. One example include the additional support structure 315 configured along the side of the chamber wall 152 having the access port 156 to provide mechanical support and structural integrity to the chamber wall 152 of the chamber body 102. As shown in FIG. 3, the additional support structure 315 may also be connected to the elongated support structures 312. Other examples may include additional support structures positioned below other sides of the chamber wall 152.

Other configurations and positioning for the components of the chamber support assembly 310 can also be used without deviating form the scope of the invention. In the configuration shown in FIG. 4, the lateral support structures 314, 316 are disposed in an orientation that is generally transverse to the elongated base support structures 312. It is understood that the chamber support assembly 310 is attached to the lower side of the chamber bottom 154 and it is contemplated that the elongated base support structures 312, the lateral support structures 314, 316, the cross support structures 318, and the additional support structure 315 may, in one embodiment, be connected to each other and do not move relative to each other during substrate processing. Also, while two elongated base support structures 312, two lateral support structures 314, two lateral support structures 316, four cross support structures 318, and one additional support structure 315 are shown, it is to be under stood that any number of the elongated base support structures 312, the lateral support structures 314, 316, the cross support structures 318, and the additional support structure 315 may be used.

In one embodiment, a method of reinforcing a chamber bottom of a vacuum chamber is provided. The method may include providing a plurality of elongated base support structures in a first direction, providing a plurality of lateral support structures in a second direction, and attaching the elongated base support structures and the lateral support structures to the chamber bottom. In one embodiment, the first and the second direction are perpendicular to each other. In addition, the method may further include providing a plurality of cross support structures and a plurality of additional support structure and attaching these structure to the chamber bottom of the process chamber.

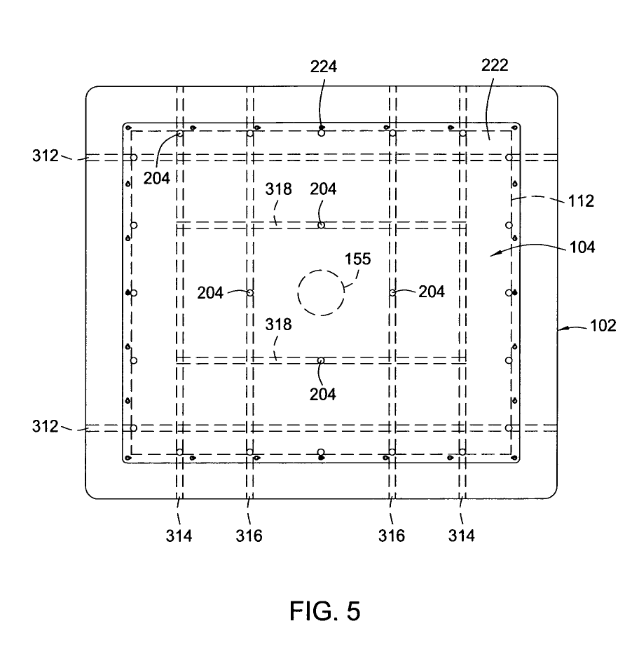

FIGS. 4 and 5 are exemplary sectional view and top view of the chamber body 102 in accordance with one or more aspects of the invention. In one embodiment, the chamber bottom 154 of the chamber body 102 may further include the plurality of substrate support pins 202 to support the substrate 112 being transferred into and out of the process chamber 100 through the access port 156. In another embodiment, the plurality of substrate support pins 202 are attached to an interior side of the chamber bottom 154. The substrate support pins 202 are able to pass through a plurality of substrate support pin holes 204 on the susceptor 222 in order to receive the substrate 112 above the susceptor 222 when the susceptor 222 is moved down to the lower substrate loading/unloading position. The substrate support pins 202 facilitate the placement or removal of the substrate 112 by a transfer robot or other transfer mechanism disposed exterior to the process chamber 100 and entered through the access port 156. The substrate support pins 202 generally include a length “L” when attached on the bottom 154. In one embodiment, the length “L” is larger than the height “H” between the chamber bottom 154 and the access port 156 in order to provide space for loading and unloading the substrate 112 by the transfer robot.

The substrate support pins 202 can be made of a metal or a metal alloy material, such as aluminum, stainless steel, etc. Alternatively, the substrate support pins 202 can be made of an insulating material, such as ceramic materials, anodized aluminum oxides materials, engineering plastic materials, among others. In one embodiment, the substrate support pins 202 are made of stainless steel material. The substrate support pins 202 can be attached or bonded to the chamber bottom 154 using mating, welding, and/or other alignment mechanisms known in the art. For example, the substrate support pins 202 may be attached to the chamber bottom 154 through male or female threading alignments and secured to a plurality of holes on the main body of the chamber bottom 154, thereby keeping the substrate 112 at a leveled position above the susceptor 222. Alternatively, the substrate support pins 202 may be supported by a movable support pin plate in order to be moved up and down to receive the substrate 112 thereon. Other configurations and positioning for the substrate support pins 202 can also be used.

Accordingly, the susceptor 222 of the invention includes the substrate support pin holes 204 adapted to align with the substrate support pins 202 for the substrate support pins to pass through and may further include additional alignment mechanisms, such as one or more alignment pins 224 adapted to align the substrate support assembly 104 to the shadow frame 158. The alignment pins 224 can be made of an insulating material, such as ceramic materials, anodized aluminum oxides materials, engineering plastics, among others, in order to insulate the heated susceptor 222 from the shadow frame 158, chamber walls 152, and other chamber components.

As shown in FIG. 4, the substrate support pins 202 may need to be positioned at the peripheral portions of the chamber bottom 154, thus, near the perimeter of the substrate 112, in order to support the substrate 112. However, when a substrate of a very large dimension is placed on the substrate support pins 202 and/or the susceptor 222, substrate deflection or sagging (i.e., change in vertical positions when placing the substrate flat) can occur. Thus, the invention provides additional substrate support pins 202 positioned spatially apart near the inner portions of the bottom 154. In addition, the numbers and positions of the substrate support pins 202 and the substrate support pin holes 204 on the susceptor 222 are optimized such that substrate deflection or sagging is reduced without interfering with other components of the substrate support assembly 104. In one embodiment, the substrate support pins 202 are configured to be positioned equally apart along the edges of the chamber bottom 154 and distributed spatially in equal distances along mid-lines across the lift assembly port 155 in order to minimize deflection and sagging of the substrate 112 as supported by the substrate support assembly 104 positioned through the lift assembly port 155. FIG. 4 demonstrates one example of positioning the substrate support pins 202 at the respective locations.

Accordingly, a method of transferring a substrate into a vacuum chamber is provided. The vacuum chamber may include a plurality of substrate support pins adapted to support the substrate during substrate loading and unloading. In addition, the vacuum chamber may include a susceptor adapted to support the substrate during substrate processing. The method of transferring the substrate includes providing the plurality of the substrate support pins attached to an interior side of the bottom of the vacuum chamber and placing the substrate onto the plurality of the substrate support pins. Then, the suscpetor is adapted to move up and down in a vertical direction, in the same direction to the plurality of the substrate support pins attached to the chamber bottom, and the substrate can be lifted from the plurality of the substrate support pins for loading and unloading the substrate.

One embodiment of the invention provides that various support structures of the chamber support assembly 310 are positioned below and relative to the locations of the substrate support pins 202 attached to the upper side of the chamber bottom 154 to ensure enough mechanical support and relatively uniform contact between the substrate support pins 202 and the substrate 112 and obtain a relatively planar (flat) and leveled surface of the substrate 112 without substrate sagging or deflection when the substrate 112 is supported by the substrate support pins 202.

Another embodiment of the invention provides that the substrate support pins 202 are supported by the chamber bottom 154 being reinforced with the elongated base support structures 312, the lateral support structures 314, 316, and the cross support structures 318 near the respective pin locations such that the substrate support pins 202 are kept still and fixed at the respective pin locations during substrate loading and unloading and can not move vertically along with the susceptor 222 or vibrate horizontally, as seen in other substrate support pin designs. The substrate support pins 202 having the length “L”, when frequently being moved up and down in order to place the substrate 112 thereon, may easily be jammed, leading to substrate breakage. For example, free floating support pins actuated by a lift pin plate may be easily bended or stuck between the susceptor and the lift pin plate. In one aspect, it is advantageous to configure the substrate support pins 202 attached to an interior side of the chamber bottom 154 such that the substrate support pins 202 can maintain in a vertical orientation with respect to the susceptor 222. As a result, the substrate support pins 202 can easily align with the substrate support pin holes 204 on the susceptor 222 and there is no separate lift pin plate in the vacuum chamber in order to save space.

Accordingly, the invention provides a reinforced chamber body having the chamber support assembly 310 such that the weight of the chamber body can be reduced and the reinforced chamber body provides sufficient mechanical support and structural integrity to various components of the process chamber 100. Although several preferred embodiments which incorporate the teachings of the present invention have been shown and described in detail, those skilled in the art can readily devise many other varied embodiments that still incorporate these teachings. While the foregoing is directed to embodiments of the present invention, other and further embodiments of the invention may be devised without departing from the basic scope thereof, and the scope thereof is determined by the claims that follow.

We claim:

1. A chamber body for a chamber adapted to support a large area substrate therein, comprising:
one or more chamber walls;
a chamber bottom; and
a chamber support assembly attached an exterior side of the chamber bottom, comprising:
one or more elongated base support structures; and
one or more lateral support structures.

2. The chamber body of claim 1, wherein the one or more elongated base support structures and the one or more lateral support structures comprise a height of about four inches or larger.

3. The chamber body of claim 1, wherein the one or more elongated base support structures and the one or more lateral support structures comprise a stainless steel material.

4. The chamber body of claim 1, wherein the chamber support assembly further comprises one or more cross support structures connected to the one or more lateral support structures.

5. The chamber body of claim 1, wherein the chamber support assembly further comprises one or more additional support structures positioned below the one or more chamber walls.

6. The chamber body of claim 1, wherein the one or more elongated base support structures and the one or more lateral support structures are connected to each other.

7. The chamber body of claim 1, further comprising a plurality of substrate support pins attached to an interior side of the chamber bottom and adapted to support a large area rectangular substrate of about one square meter or larger thereon.

8. The chamber body of claim 7, wherein the one or more elongated base support structures and the one or more lateral support structures of the chamber support assembly are positioned below and relative to the locations of the plurality of the substrate support pins to ensure mechanical support for the plurality of the substrate support pins.

9. The chamber body of claim 1, wherein the one or more chamber walls and the chamber bottom comprises a thickness of about one inch or less.

10. The chamber body of claim 1, wherein the one or more elongated base support structures and the one or more lateral support structures comprises a thickness of about two inches or less.

11. A process chamber for processing a large area substrate therein, comprising:
a chamber body comprising one or more chamber walls and a chamber bottom; and
a plurality of substrate support pins attached to an interior side of the chamber bottom and adapted to support the large area substrate.

12. The process chamber of claim 11, further comprising a susceptor having a plurality of substrate support pin holes thereon adapted for the plurality of the substrate support pins to pass through.

13. The process chamber of claim 12, wherein the plurality of substrate support pins are adapted to maintain in an vertical orientation with respect to the susceptor.

14. The process chamber of claim 11, wherein the one or more chamber walls and the chamber bottom comprise a thickness of about one inch or less.

15. The process chamber of claim 11, wherein the plurality of substrate support pins are configured to support a large area rectangular substrate of about one square meter or larger.

16. A method of reinforcing a chamber bottom of a vacuum chamber, comprising:
providing a plurality of elongated base support structures in a first direction;
providing a plurality of lateral support structures in a second direction; and
attaching the elongated base support structures and the lateral support structures to the chamber bottom of the vacuum chamber.

17. The method of claim 16, wherein the first and the second direction are perpendicular to each other.

18. The method of claim 16, further comprising:
providing a plurality of cross support structures and a plurality of additional support structure; and
attaching the plurality of cross support structures and the plurality of additional support structure to the chamber bottom of the vacuum chamber.

19. A method of transferring a substrate into a chamber having a susceptor therein, comprising:
providing a plurality of substrate support pins attached to an interior side of the bottom of the chamber;
placing the substrate onto the plurality of the substrate support pins; and
moving the susceptor in a vertical direction to lift the substrate from the plurality of the substrate support pins.

20. The method of claim 19, wherein the susceptor comprises a plurality of substrate support pin holes corresponding to the plurality of the substrate support pins and adapted for the plurality of the substrate support pins to pass through.
